(19) United States
(12) Patent Application Publication
(10) Pub. No.: US 2025/0392230 A1
(43) Pub. Date: Dec. 25, 2025

(54) POWER CONVERSION APPARATUS

(71) Applicant: Mitsubishi Electric Corporation, Tokyo (JP)

(72) Inventors: Zhengfeng LI, Tokyo (JP); Nobuya NISHIDA, Tokyo (JP); Hiroki HIDAKA, Tokyo (JP)

(73) Assignee: Mitsubishi Electric Corporation, Tokyo (JP)

(21) Appl. No.: 19/190,023

(22) Filed: Apr. 25, 2025

(30) Foreign Application Priority Data
Jun. 25, 2024 (JP) 2024-101878

(51) Int. Cl. H02M 7/00; H05K 7/14

(52) U.S. Cl. CPC H02M 7/003; H05K 7/14329

(57) ABSTRACT

A power conversion apparatus converting direct electrical power to alternating electrical power includes a plurality of semiconductor modules and an alternating current busbar connected in common to output terminals of the plurality of semiconductor modules, wherein the alternating current busbar has a multilayer structure divided into a plurality of pieces in a thickness direction, and includes an insulating layer partially provided between an upper plate on an upper side and a lower plate on a lower side.

### BACKGROUND

### Technical Field

The present disclosure relates to a power conversion apparatus, and particularly to a power conversion apparatus in which three semiconductor modules are parallelly connected.

### Description of the Background Art

A half-bridge module in which two insulated gate bipolar transistors (IGBT) are connected in series is used as a basic unit of a converter and an inverter, and a plurality of half-bridge modules are parallelly connected to increase output electrical power and are used in some cases.

For example, International Publication No. 2024/048066 discloses a configuration that three half-bridge modules are parallelly connected to output alternating current of U phase, V phase, and W phase.

### SUMMARY

When direct current is converted into alternating current using a half-bridge module in which IGBTs are connected in series, alternating current in which high frequency is superimposed is generated by a high-speed switching operation of the IGBT. Since skin effect occurs, and heat is locally generated in a surface of an alternating current busbar as an output part, countermeasures against heat are necessary. However, International Publication No. 2024/048066 does not particularly disclose a problem of the alternating current in which the high frequency is superimposed.

An object of the present disclosure is to provide a power conversion apparatus capable of suppressing local heat generation even when skin effect occurs in an alternating current busbar.

A power conversion apparatus according to the present disclosure is a power conversion apparatus converting direct electrical power to alternating electrical power, including a plurality of semiconductor modules and an alternating current busbar connected in common to output terminals of the plurality of semiconductor modules, wherein the alternating current busbar has a multilayer structure divided into a plurality of pieces in a thickness direction, and includes an insulating layer partially provided between an upper plate on an upper side and a lower plate on a lower side.

According to the power conversion apparatus in the present disclosure, the insulating layer is partially provided between the upper plate on the upper side and a lower plate on the lower side. Since a conduction path of alternating current is increased, the power conversion apparatus in which influence of skin effect can be simulatively reduced and local heat generation in the alternating current busbar is suppressed can be obtained.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a perspective view illustrating a configuration of a power stack in which three semiconductor modules are parallelly connected.

FIG. 2 is a circuit diagram explaining a general three-phase alternating current inverter.

FIG. 3 is a waveform chart illustrating alternating current in which high frequency is superimposed.

FIG. 4 is a perspective view illustrating a configuration of an alternating current busbar according to an embodiment 1 in the present disclosure.

FIG. 5 is an exploded perspective view of the alternating current busbar according to the embodiment 1 in the present disclosure.

FIG. 6 is a diagram illustrating a concept of skin effect.

FIG. 7 is an exploded perspective view of an alternating current busbar according to a modification example 1 of the embodiment 1 in the present disclosure.

FIG. 8 is an exploded perspective view of an alternating current busbar according to a modification example 2 of the embodiment 1 in the present disclosure.

FIG. 9 is an exploded perspective view of an alternating current busbar according to a modification example 3 of the embodiment 1 in the present disclosure.

FIG. 10 is a perspective view illustrating a configuration of an alternating current busbar according to an embodiment 2 in the present disclosure.

FIG. 11 is a diagram schematically illustrating a flow of current in the alternating current busbar according to the embodiment 2 in the present disclosure.

FIG. 12 is a perspective view illustrating a configuration of an alternating current busbar according to an embodiment 3 in the present disclosure.

FIG. 13 is a perspective view illustrating a configuration of the alternating current busbar according to the embodiment 3 in the present disclosure.

### DESCRIPTION OF THE PREFERRED EMBODIMENTS

### Introduction

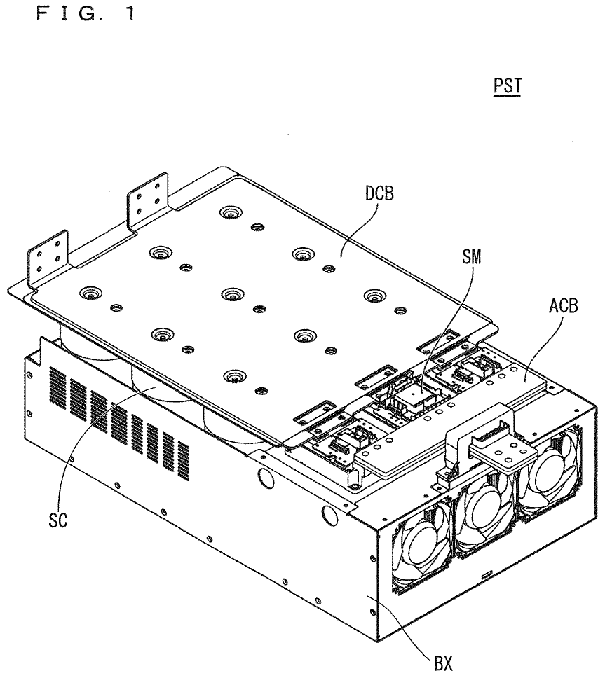

FIG. 1 is a perspective view illustrating a configuration of a power stack PST in which three semiconductor modules SM are parallelly connected. As illustrated in FIG. 1, a power stack PST includes a chassis BX housing a plurality of smoothing capacitors SC, a direct current busbar DCB mounted to an upper part of the chassis BX, three semiconductor modules SM connected to the direct current busbar DCB, and an alternating current busbar ACB connected in common to output terminals of three semiconductor modules SM. Although cooling fan and an input-output part of a cooling medium are also provided to the power stack PST, but have a tenuous relationship with the present disclosure; thus, the description is omitted.

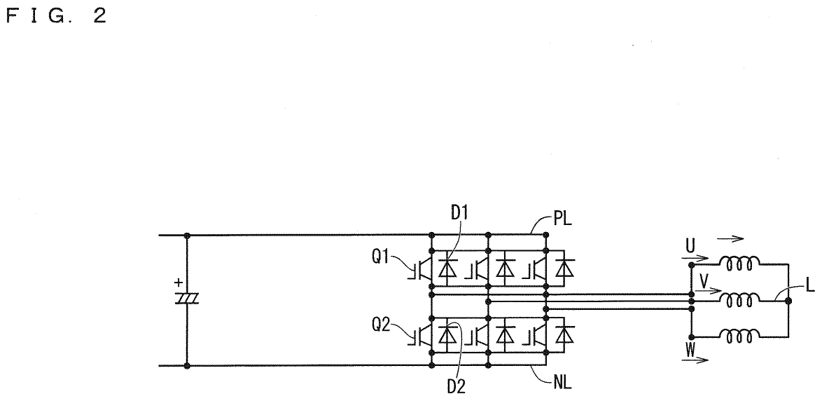

FIG. 2 is a circuit diagram explaining a general three-phase alternating current inverter. As illustrated in FIG. 2, an IGBT Q1 and an IGBT Q2 are connected in series between a main power source line PL as a high potential side (P side) and a main power source line NL as a low potential side (N side) to constitute a half-bridge module. Diodes D1 and D2 are antiparallelly connected to the IGBT Q1 and the IGBT Q2, respectively. A connection node of the IGBT Q1 and the IGBT Q2 is a U terminal outputting a U phase, and is connected to an inductive load L such as a motor. Although half-bridge modules outputting a V phase and a W phase are also disclosed in FIG. 2, the description is omitted.

Three power stacks PST in FIG. 1 are necessary to obtain a three-phase alternating current inverter illustrated in FIG. 2. That is to say, the power stack PCT in FIG. 1 corresponds to a half-bridge module of one phase.

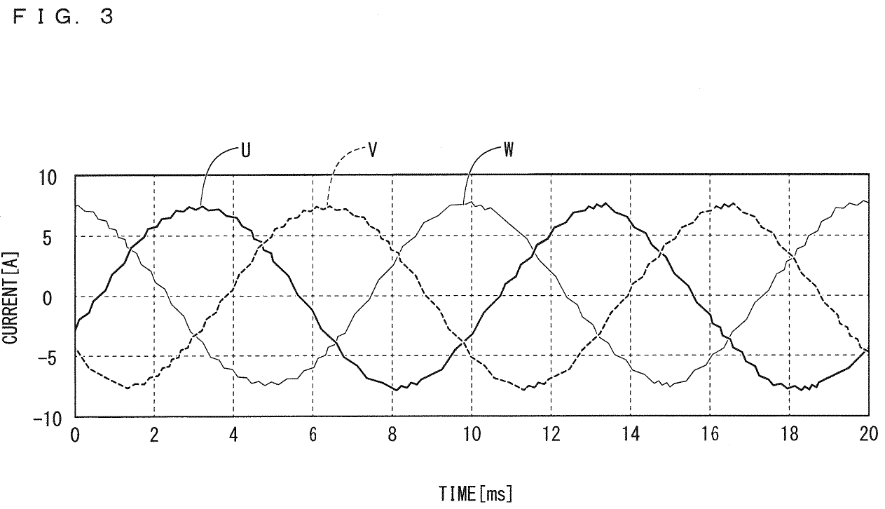

As described above, when the direct current is converted into the alternating current using the half-bridge module in which the IGBTs are connected in series, the alternating current in which the high frequency is superimposed is generated by high-speed switching frequency reaching several tens of kilohertz of the inverter. FIG. 3 is a waveform chart illustrating alternating current in which high frequency is superimposed.

In FIG. 3, a lateral axis indicates a time [ms], and a vertical axis indicates current [A]. As illustrated in FIG. 3, high frequency is superimposed to each alternating current waveform of the U phase, the V phase, and the W phase in which frequency is approximately 100 Hz, and the waveform is not smooth. In such alternating current in which the high frequency is superimposed, skin effect in which current flows only in a surface of a conductor occurs when the current flows in the conductor, and heat is locally generated.

Used in some cases are terms each indicating a specific position and direction such as “up”, “down”, “side”, “front”, and “back”, for example, in the description hereinafter; however, these terms are used for convenience of easy understanding of contents of the embodiments, and do not relate to a direction in an actual use.

Since the diagrams are schematically illustrated, a mutual relationship of sizes and positions of images respectively illustrated in the different diagrams is not necessarily illustrated accurately, but may be appropriately changed. In the description hereinafter, the same reference numerals will be assigned to the similar constituent elements in the diagrams, and the constituent elements having the same reference numeral have the similar name and function. Accordingly, the detailed description on them may be omitted in some cases.

An alternating current busbar suppressing local heat generation is described in embodiments according to the present disclosure hereinafter.

### Embodiment 1

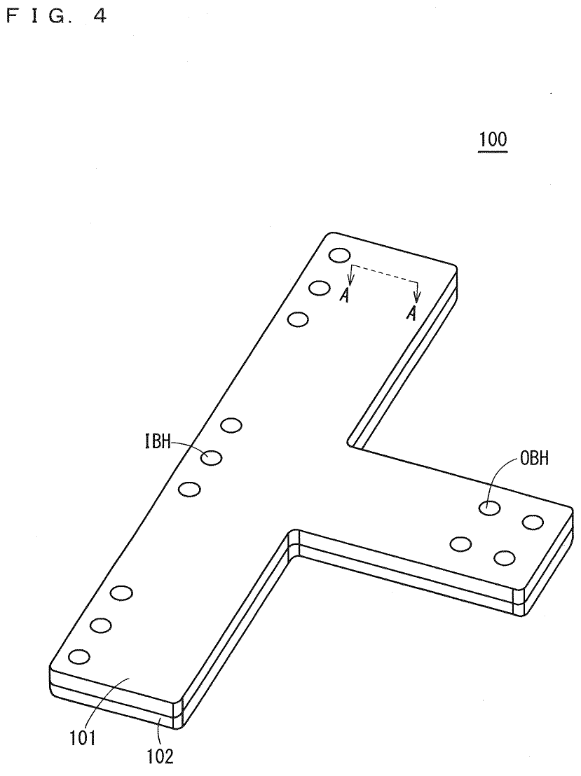

FIG. 4 is a perspective view illustrating a configuration of an alternating current busbar 100 according to an embodiment 1 in the present disclosure. The alternating current busbar 100 illustrated in FIG. 4 corresponds to the alternating current busbar ACB of the power stack PST described using FIG. 1, and is connected in common to output terminals (not shown) of three semiconductor modules SM illustrated in FIG. 1. The semiconductor module is not illustrated for convenience, but is fastened to an output terminal of each semiconductor module via a plurality of fastening holes IBH (first passing hole) as an input part provided to one long side of a part of the alternating current busbar 100 having a T-like shape in a plan view corresponding to a head part of the T-like shape. In this example, three fastening holes IBH are disposed in a row for one semiconductor module, and nine fastening holes IBH in total are provided; however, the number of the fastening holes IBH is not limited thereto. Fastening to the output terminal is performed via a bolt or a nut.

A plurality of fastening holes OBH as an output part for being connected to an external wiring (not shown) are provided to an end part of a part corresponding to a leg part of the T-like shape on a side opposite to the fastening holes IBH. Although four fastening holes OBH (second passing holes) are provided in this example, the number of the fastening holes OBH is not limited thereto. Fastening to the external wiring is performed via a bolt or a nut.

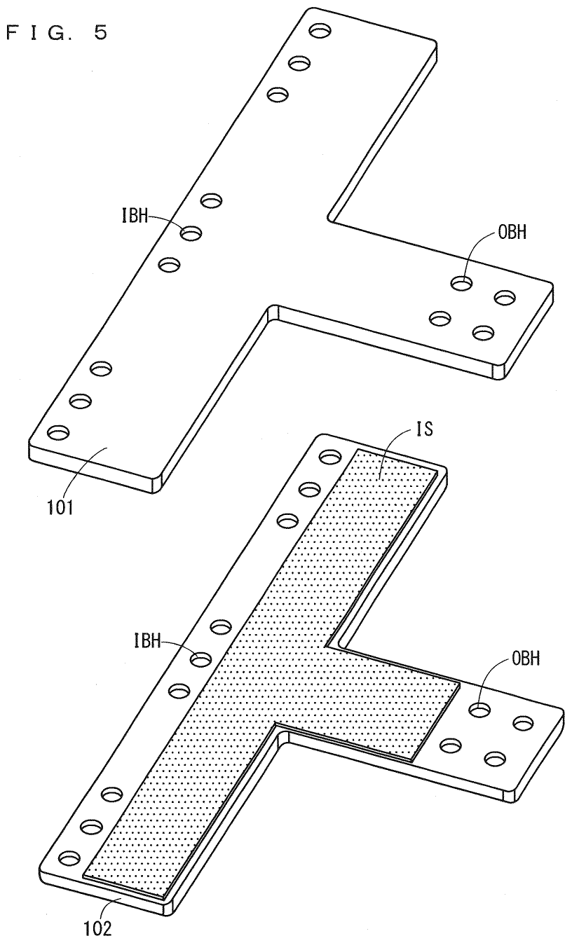

The alternating current busbar 100 is made by overlapping an upper plate 101 (first conductive plate) and a lower plate 102 (second conductive plate) such as copper having high conductivity, and FIG. 5 illustrates a state where they are separated from each other.

As illustrated in FIG. 5, an insulating object IS (insulating layer) is inserted between the upper plate 101 and the lower plate 102 having the T-like shape in a plan view. The insulating object IS has a T-like shape in the manner similar to the upper plate 101 and the lower plate 102, and has a size and shape so as not to cover the arrangement of the fastening holes IBH and the fastening holes OBH. An insulating sheet having a thickness of 0.5 mm, for example, can be used as the insulating object IS, and Nomex (registered trademark) can be used, for example. A liquid insulating material such as HumiSeal (registered trademark) used for insulating coating of an electrical substrate can be applied and used. The thickness of the insulating object IS is not limited to 0.5 mm, but may be smaller as long as the insulating object IS can electrically insulate the upper plate 101 and the lower plate 102.

In a state where the upper plate 101 and the lower plate 102 are fastened via the fastening hole IBH, the input part of the upper plate 101 and the input part of the lower plate 102 are electrically connected to each other. In a state the upper plate 101 and the lower plate 102 are fastened via the fastening hole OBH, the output part of the upper plate 101 and the output part of the lower plate 102 are electrically connected to each other.

In assembling the alternating current busbar 100, the alternating current busbar 100 can be obtained by overlapping the upper plate 101 after locating or applying and drying the insulating object IS on the lower plate 102.

Since the insulating object IS is inserted between the upper plate 101 and the lower plate 102, the upper plate 101 and the lower plate 102 are insulated from each other in a part in which the insulating object IS is provided, and current separately flows in the upper plate 101 and the lower plate 102.

That is to say, the current flowing in the alternating current busbar 100 flows as follows. Firstly, the current is inputted from the output terminal of the semiconductor module to the input part to which the upper plate 101 and the lower plate 102 are electrically connected. The current inputted from the input part is divided into current flowing toward the output part through the upper plate 101 and current flowing toward the output part through the lower plate 102 in the part in which the insulating object IS is provided. Herein, a direction of the current flowing in the upper plate 101 is the same as that of the current flowing in the lower plate 102 in the part in which the insulating object IS is provided. The upper plate 101 and the lower plate 102 are electrically connected in the output part, and the current flowing in the upper plate 101 and the current flowing in the lower plate 102 are combined in the output part, and flows to the external wiring. That is to say, the current flowing in the alternating current busbar 100 is inputted from the input part to the alternating current busbar 100, is divided into the current flowing to the output part from the input part through the upper plate 101 and the current flowing to the output part from the input part through the lower plate 102, is combined in the output part, and is then output to the external wiring.

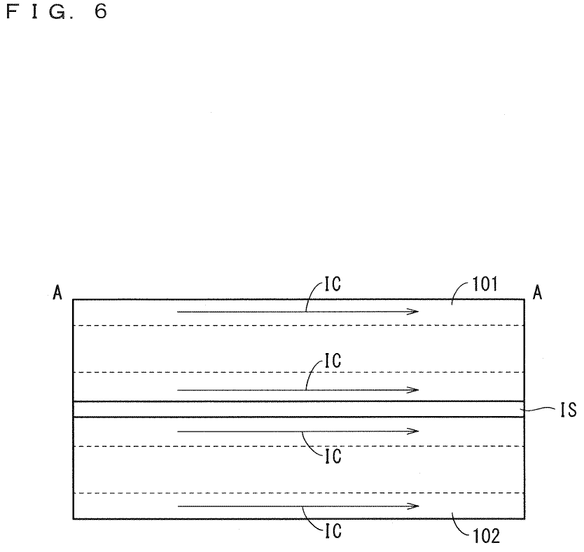

As described above, the alternating current in which the high frequency is superimposed causes skin effect in which current flows only to the surface of the conductor when the current flows in the conductor. FIG. 6 is a diagram illustrating a concept of the skin effect. FIG. 6 is a partial cross sectional view of the alternating current busbar 100 along an A-A line illustrated in FIG. 4, and schematically illustrates a part in which the insulating object IS is provided between the upper plate 101 and the lower plate 102.

As illustrated in FIG. 6, current IC separately flows in the upper plate 101 and the lower plate 102 by presence of the insulating object IS, further flows only in upper and lower surfaces of the upper plate 101 and the lower plate 102, and does not flow in a center part enclosed by a broken line. This is skin effect. A skin depth of a copper material is 0.65 mm at frequency of 10 kHz, and gets smaller as the frequency gets higher.

A region in which the current IC flows in FIG. 6 is a region regulated by the skin depth, and when a thickness of each of the upper plate 101 and the lower plate 102 is 6 mm, for example, the current IC flows only in a region of 1/10 of the thickness thereof at frequency of 10 KHz.

When the insulating object IS is not provided and the alternating current busbar 100 is made by a single plate, the current flows only in upper and lower surfaces of the single plate; thus, electrical resistance gets large and the current is concentrated.

However, when the insulating object IS is provided as illustrated in FIG. 6, an area of a conduction path is doubled. Influence of skin effect can be simulatively reduced, and concentration of the current in the alternating current busbar 100 can be reduced.

Although the alternating current busbar 100 has a double-layer structure of the upper plate 101 and the lower plate 102, the number of overlapped plate materials is not limited to two. When the four plates are overlapped and the insulating object IS is inserted therebetween, the area of the conduction path is quadrupled. The number of overlapped plate materials can be further increased.

When the thickness of each of the upper plate 101 and the lower plate 102 is 6 mm, for example, the thickness of the alternating current busbar 100 is approximately 12 mm. This is to ensure that the temperature change of the busbar is equal to or smaller than 40° C. When the thickness is approximately 10 to 15 mm, the temperature change of the busbar can be equal to or smaller than 40° C.

### Modification Example 1

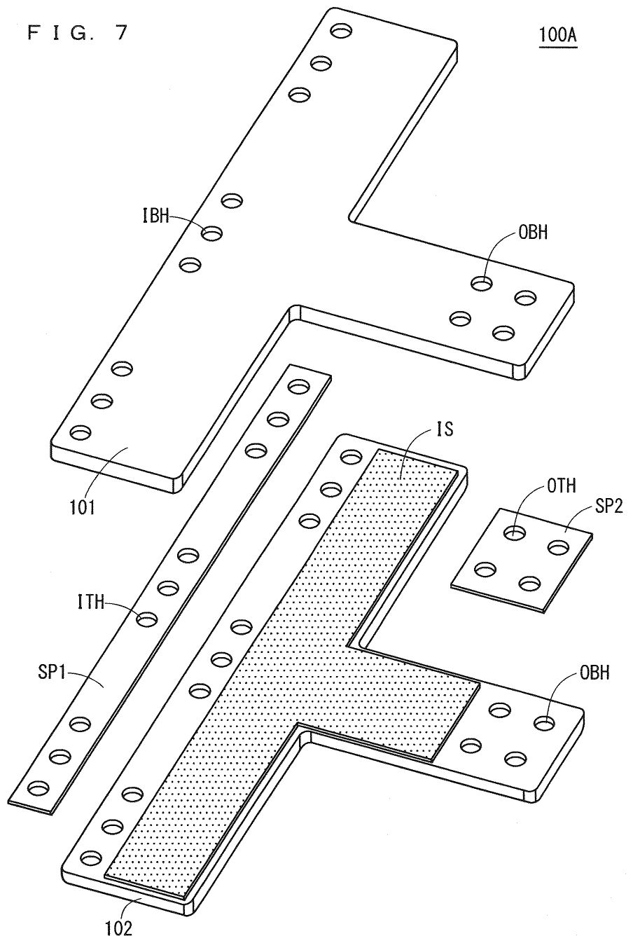

FIG. 7 is an exploded perspective view illustrating a configuration of an alternating current busbar 100A according to a modification example 1 of the embodiment 1, and corresponds to the state illustrated in FIG. 5 in which the upper plate 101 and the lower plate 102 are separated. In FIG. 7, the same reference numerals are assigned to the same configuration as those of the alternating current busbar 100 described using FIG. 5, and a repetitive description will be omitted.

As illustrated in FIG. 7, a spacer SP1 (first spacer) and a spacer SP2 (second spacer) are inserted between the upper plate 101 and the lower plate 102 in addition to the insulating object IS in the alternating current busbar 100A. The spacer SP1 and the spacer SP2 are provided in a region in which the insulating object IS is not disposed. The spacer SP1 is disposed in a region in which nine fastening holes IBH are provided, has an elongated rectangular shape in a plan view, and includes nine passing holes ITH (third passing hole) to correspond to the fastening holes IBH. The spacer SP2 is disposed in a region in which four fastening holes OBH are provided, has a rectangular shape in a plan view, and includes four passing holes OTH (fourth passing hole) to correspond to the fastening holes OBH.

The spacers SP1 and SP2 are formed of a conductor having a thickness of 0.5 mm, for example, and the same copper material as the busbar can be used as a material. However, any conductor is applicable as long as there is no problem of corrosion due to contact of dissimilar metal, and a material having high conductivity is preferable from a viewpoint of heat generation. The thickness thereof is set to 0.5 mm to comply with the thickness of the insulating object IS, but may also be smaller than that of the insulating object IS. The spacers SP1 and SP2 having a smaller thickness are more preferable, and a resistance component for the spacer can be reduced as the spacers gets thinner.

Inner surfaces of the passing hole ITH and the passing hole OTH of the spacers SP1 and SP2 can be made to serve as an insulating film by forming an oxide film, for example.

Since the spacers SP1 and SP2 are inserted between the upper plate 101 and the lower plate 102, there is no gap between the upper plate 101 and the lower plate 102 in the fastening region in which the fastening holes IBH and OBH are provided. The upper plate 101 and the lower plate 102 can be fastened with no gap in fastening to the output terminal of the semiconductor module, for example; thus, contact resistance can be reduced, and a resistance component can be reduced.

### Modification Example 2

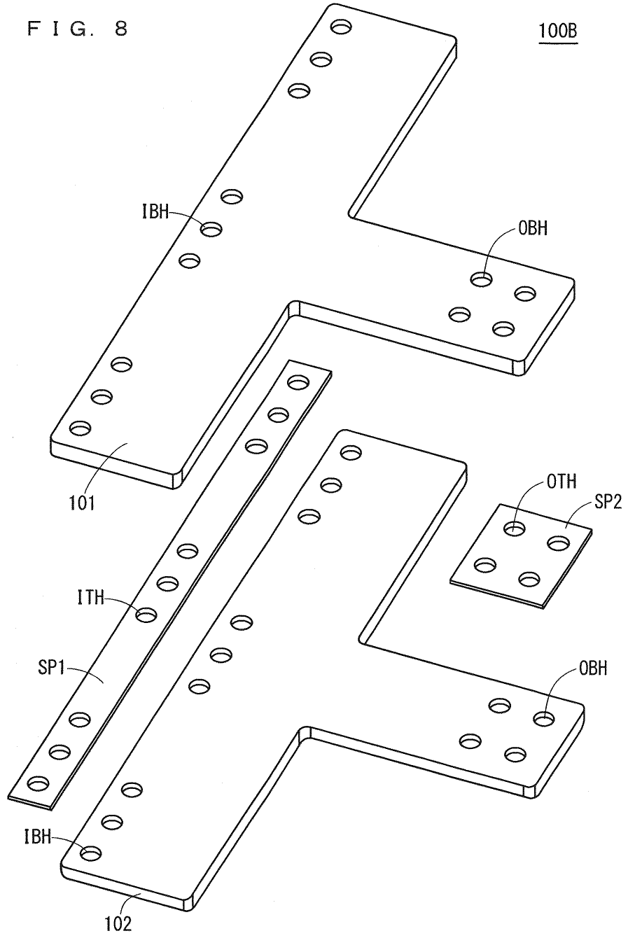

FIG. 8 is an exploded perspective view illustrating a configuration of an alternating current busbar 100B according to a modification example 2 of the embodiment 1, and corresponds to the state illustrated in FIG. 5 in which the upper plate 101 and the lower plate 102 are separated. In FIG. 8, the same reference numerals are assigned to the same configuration as those of the alternating current busbar 100A described using FIG. 7, and a repetitive description will be omitted.

As illustrated in FIG. 8, the alternating current busbar 100B does not include the insulating object IS between the upper plate 101 and the lower plate 102, and only the spacers SP1 and SP2 are inserted therebetween. An arrangement position of the spacers SP1 and SP2 is the same as that in the alternating current busbar 100A.

Since only the spaces SP1 and SP2 are provided between the upper plate 101 and the lower plate 102, a gap, that is to say, an air layer as an insulating layer is located in a region in which the spacers SP1 and SP2 are not provided, that is to say, a region in which the insulating object IS is provided, and the current separately flows in the upper plate 101 and the lower plate 102 in the manner similar to the case where the insulating object IS is provided. The area of the conduction path is doubled, influence of skin effect can be simulatively reduced, and concentration of the current in the alternating current busbar 100B can be reduced.

Since the insulating object IS is not provided, manufacturing cost can be reduced, and assembling can also be easily performed.

### Modification Example 3

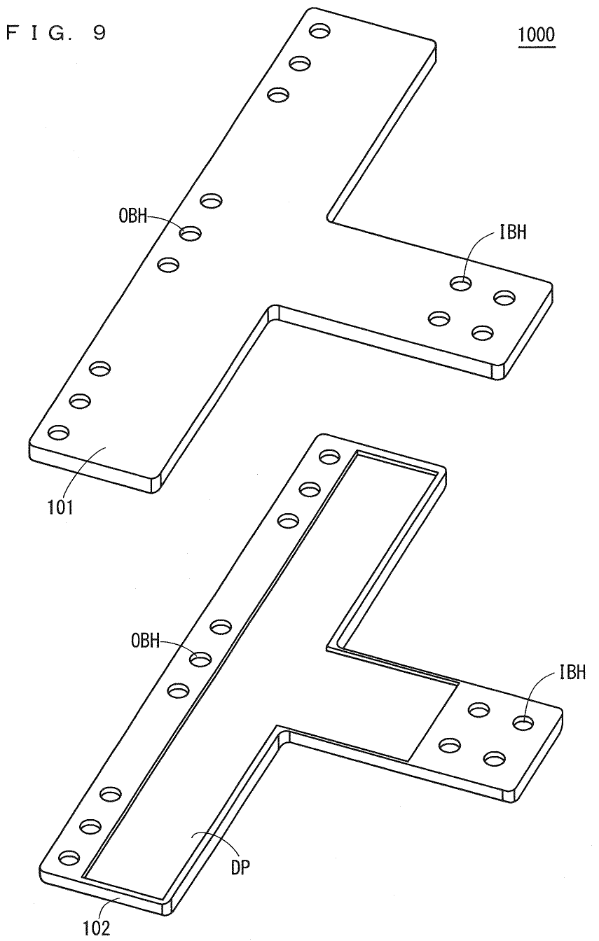

FIG. 9 is an exploded perspective view illustrating a configuration of an alternating current busbar 100C according to a modification example 3 of the embodiment 1, and corresponds to the state illustrated in FIG. 5 in which the upper plate 101 and the lower plate 102 are separated. In FIG. 8, the same reference numerals are assigned to the same configuration as those of the alternating current busbar 100 described using FIG. 5, and a repetitive description will be omitted.

As illustrated in FIG. 9, the alternating current busbar 100C does not include the insulating object IS and the spaces SP1 and SP2 between the upper plate 101 and the lower plate 102, and the region in which the insulating object IS is provided in the lower plate 102 is a concave part DP.

Since the concave part DP is provided, a gap, that is to say, air as an insulating layer is located between the upper plate 101 and the lower plate 102, and the current separately flows in the upper plate 101 and the lower plate 102 in the manner similar to the case where the insulating object IS is provided. The area of the conduction path is doubled, influence of skin effect can be simulatively reduced, and concentration of the current in the alternating current busbar 100C can be reduced.

Since the concave part DP is provided in the lower plate 102, a shape is different between the upper plate 101 and the lower plate 102.

The concave part DP can also be provided in a surface of the upper plate 101 facing the lower plate 102, and in such a case, the shape is the same between the upper plate 101 and the lower plate 102. Since the shape is the same between the upper plate 101 and the lower plate 102, they need not be made differently. Thus, manufacturing cost can be reduced, and avoided is a risk that the upper plate 101 and the lower plate 102 are wrongly taken in assembling.

When the concave part DP is provided to the lower plate 102, a depth of the concave part DP can be 0.5 mm, for example. When the same concave part is provided to the surface of the upper plate 101 facing the lower plate 102, a depth of each concave part can be set so that a gap having a width of 0.5 mm in total can be made. A width of the gap by the concave parts is not limited to 0.5 mm.

Since the insulating object IS and the spacer SP1 and SP2 are not provided, manufacturing cost can be reduced, and assembling can be easily performed.

### Embodiment 2

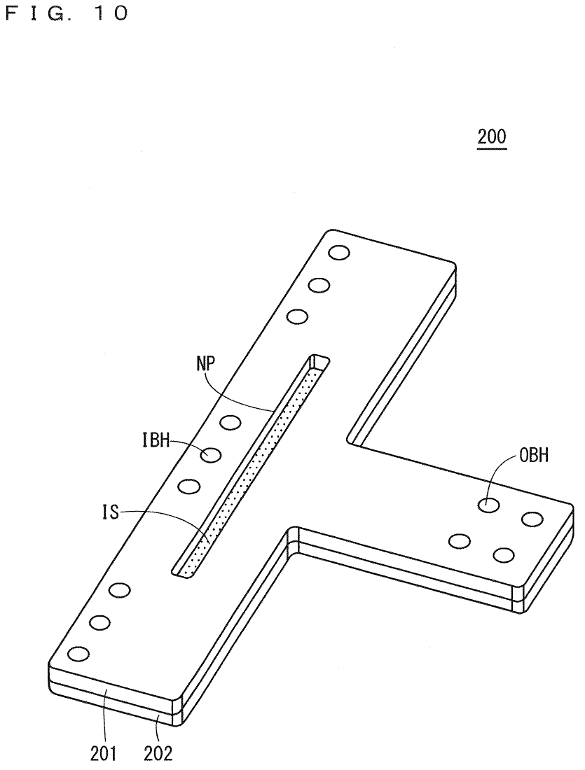

FIG. 10 is a perspective view illustrating a configuration of an alternating current busbar 200 according to an embodiment 2 in the present disclosure. The alternating current busbar 200 illustrated in FIG. 10 is different from the alternating current busbar 100 described using FIG. 4 in that the alternating current busbar 200 has a configuration that a notch part NP having an elongated shape in a plan view is provided in parallel to the arrangement of the fastening hole IBH in a center part of a part corresponding to a head part of the T-like shape. In FIG. 10, the same reference numerals are assigned to the same configuration as those of the alternating current busbar 100 described using FIG. 4, and a repetitive description will be omitted.

The notch part NP is provided to pass through an upper plate 201 and a lower plate 202. When the insulating object IS is inserted between the upper plate 201 and the lower plate 202 in the manner similar to FIG. 5, the insulating object IS is exposed in the notch part NP as illustrated in FIG. 10. As illustrated in FIG. 8 and FIG. 9, when the insulating object IS is not provided, the notch part NP is a passing hole passing through the upper plate 201 and the lower plate 202.

Since the notch part NP is provided, balance of the current flowing from the output terminal of the semiconductor module SM (FIG. 1) of the power stack PST (FIG. 1) can be uniformed.

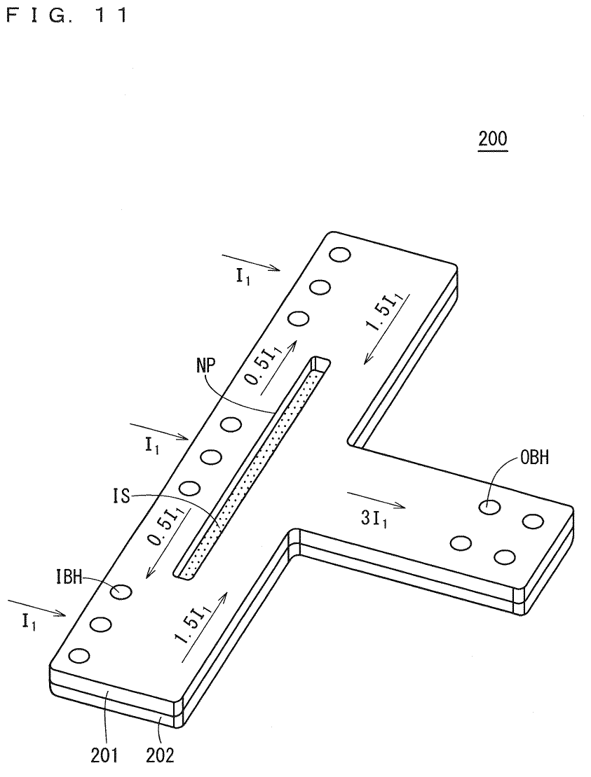

FIG. 11 is a diagram schematically illustrating a flow of the current when the current flows from nine fastening holes IBH to the alternating current busbar 200. FIG. 11 schematically illustrates that current I₁ flows from three fastening holes IBH connected one semiconductor module SM and what ratio of the current I₁ flows through the alternating current busbar 200.

As illustrated in FIG. 11, the current I₁ flowing in three fastening holes IBH in a center is divided into current 0.5 I₁ each on right and left sides. The current I₁ flowing in three fastening holes IBH on each of the right and left sides is combined with the divided 0.5 I₁ to be 1.5 I₁ for each, is combined at a part corresponding to a leg part of the T-like shape to be 3 I₁, and then flows in four fastening holes OBH in an end part of the leg part.

FIG. 11 illustrates the flow of the current in the upper plate 101, and the current also flows in the similar manner in the lower plate 102. Since the current flows in the same direction between the upper plate 101 and the lower plate 102, balance of the current is kept.

Since the notch part NP is provided in this manner, the current outputted from three semiconductor modules SM flows evenly in the busbar in a plan view. Concentration of the current is further suppressed and local heat generation in the busbar can be reduced.

A length of the notch part NP in a longitudinal direction is larger than that of an arrangement length of three fastening holes IGH in the center at least, and a lateral direction is substantially equal to a diameter of the fastening hole IBH at least.

### Embodiment 3

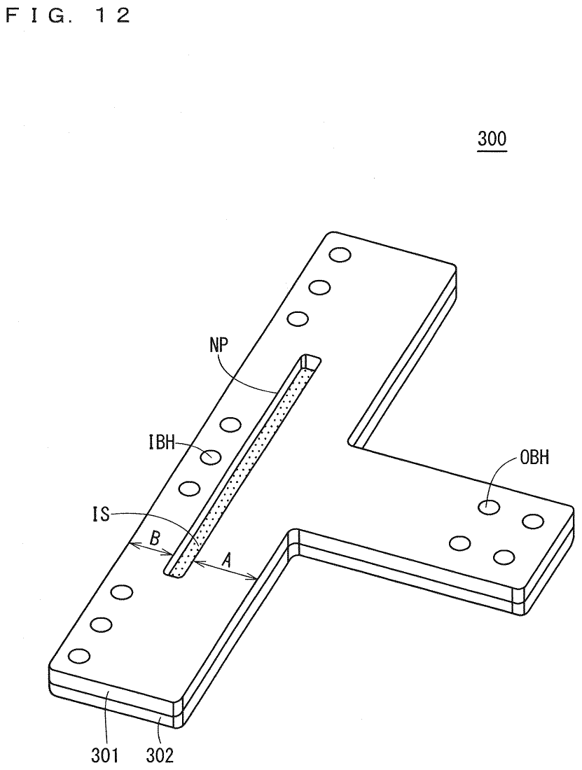

FIG. 12 is a perspective view illustrating a configuration of an alternating current busbar 300 according to an embodiment 3 in the present disclosure. In FIG. 12, the same reference numerals are assigned to the same configuration as those of the alternating current busbar 200 described using FIG. 10, and a repetitive description will be omitted.

The notch part NP is provided to pass through an upper plate 301 and a lower plate 303. When the insulating object IS is inserted between the upper plate 301 and the lower plate 302 in the manner similar to FIG. 5, the insulating object IS is exposed in the notch part NP as illustrated in FIG. 12. As illustrated in FIG. 8 and FIG. 9, when the insulating object IS is not provided, the notch part NP is a passing hole passing through the upper plate 301 and the lower plate 302.

The alternating current busbar 300 illustrated in FIG. 12 is different from the alternating current busbar 200 described using FIG. 10 in that the notch part NP is provided in a position close to the arrangement of the fastening hole IBH instead of the center part of the head part of the T-like shape.

That is to say, a length B from an edge of a first long side on a side of the fastening hole IBH to an edge of the alternating current busbar 200 on the side of the fastening hole IBH is smaller than a length A from an edge of a second long side on the side of the fastening hole IBH to an edge of the alternating current busbar 200 on a side opposite to the fastening hole IBH in two long sides of the notch part NP.

An optimal ratio between the length A and the length B is different depending on the number of parallel arrangements of the semiconductor modules SM (FIG. 1) connected to the alternating current busbar 300. That is to say, although three semiconductor modules SM are parallelly connected in FIG. 12, the number thereof is not limited to three, but any number of semiconductor modules SM may be connected. When three semiconductor modules SM are parallelly connected, A:B=approximately 3:2 is applicable, for example.

The length B is set so that a fastening member such as a bolt, a nut, and a washer can sufficiently have contact with the busbar for fastening to the semiconductor module SM.

A conduction path along which the current flows in a plan view is similar to the alternating current bus bar 200 described using FIG. 11. Since the notch part N P is provided, the current outputted from three semiconductor modules SM flows evenly in the busbar in a plan view. Concentration of the current is further suppressed and local heat generation in the busbar can be reduced.

### Embodiment 4

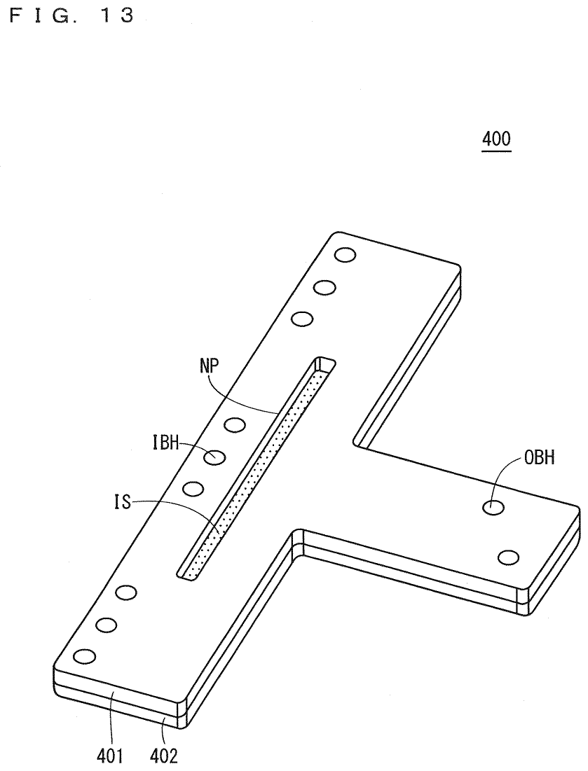

FIG. 13 is a perspective view illustrating a configuration of an alternating current busbar 400 according to an embodiment 4 in the present disclosure. The alternating current busbar 400 illustrated in FIG. 13 has a configuration that the notch part NP having the elongated shape in a plan view is provided in parallel to the arrangement of the fastening hole IBH in the center part of the part corresponding to the head part of the T-like shape in the manner similar to the alternating current busbar 200 described using FIG. 10. In FIG. 13, the same reference numerals are assigned to the same configuration as those of the alternating current busbar 200 described using FIG. 10, and a repetitive description will be omitted.

The notch part NP is provided to pass through an upper plate 401 and a lower plate 402. When the insulating object IS is inserted between the upper plate 401 and the lower plate 402 in the manner similar to FIG. 5, the insulating object IS is exposed in the notch part NP as illustrated in FIG. 13. As illustrated in FIG. 8 and FIG. 9, when the insulating object IS is not provided, the notch part NP is a passing hole passing through the upper plate 401 and the lower plate 402.

As illustrated in FIG. 13, the alternating current busbar 400 includes two fastening holes OBH for connecting an output wiring (not shown), and two fastening holes OBH are not laterally or vertically provided in a row in a plan view, but are provided at an oblique angle with respect to a short side of the leg part of the T-like shape.

Since the number of fastening holes OBH is reduced from four to two, the conduction area can be increased, and concentration of a current density can be reduced compared with the case where the number thereof is four.

That is to say, in the fastening holes IBH and OBH, a fastening member such as a bolt, a nut, or a washer is used for fastening to the semiconductor module SM (FIG. 1) and the output wiring, and these are made of a material having a higher resistance component than the busbar. For example, stainless having high strength is used in contrast to the busbar made of a copper material. Thus, when the number of fastening holes is increased and the number of fastening members is increased, fastening force is increased. However, the number of positions in which current conduction is performed via the fastening members having a high resistance value; thus, trade-off that a resistance component increases occurs.

Although it is difficult to optionally reduce the number of fastening holes IBH by reason that the current flows from the semiconductor module SM, the number of fastening holes OBH can be reduced; thus, the number of fastening members can be reduced, and a resistance component can be reduced.

When the fastening holes OBH are provided in the oblique positions in a plan view, the fastening force of being fastened to the output wiring can be increased compared with the case where the fastening holes OBH are laterally or vertically provided in a row.

### Example of Application to Power Stack

The alternating current busbar according to the embodiments 1 to 4 described above is applied as the alternating current busbar ACB of the power stack PST described using FIG. 1; thus, balance of the current in the alternating current busbar can be improved, and local concentration of the current can be reduced.

Unevenness of a heat distribution and a heat generation amount inside the busbar can be reduced, and electrical power can be effectively converted.

In the power stack PST in which three semiconductor modules SM are parallelly connected, balance of the current flowing in each semiconductor module SM is also improved; thus, variation of a lifetime of a power device can also be equalized.

Each embodiment can be arbitrarily combined, or each embodiment can be appropriately varied or omitted within a scope of the present disclosure.

The present disclosure described above is collectively described hereinafter as appendixes.

### Appendix 1

A power conversion apparatus converting direct electrical power to alternating. electrical power, comprising:
a plurality of semiconductor modules; and
an alternating current busbar connected in common to output terminals of the plurality of semiconductor modules, wherein
the alternating current busbar
has a multilayer structure divided into a plurality of pieces in a thickness direction, and
includes an insulating layer partially provided between an upper plate on an upper side and a lower plate on a lower side.

### Appendix 2

The power conversion apparatus according to Appendix 1, wherein
each of the upper plate and the lower plate includes an input part connected to the plurality of semiconductor modules and an output part connected to an outer part, and
the upper plate and the lower plate are electrically connected in the input part and the output part.

### Appendix 3

The power conversion apparatus according to Appendix 1, wherein
each of the upper plate and the lower plate includes an input part connected to the plurality of semiconductor modules and an output part connected to an outer part, and
the input part and the output part are provided on sides opposite to each other in a plan view.

### Appendix 4

The power conversion apparatus according to Appendix 2 or 3, wherein
the upper plate is a first conductive plate having a T-like shape in a plan view,
the lower plate is a second conductive plate having a T-like shape in a plan view,
the input part includes a plurality of first passing holes provided to one long side of a part corresponding to a head part of a T-like shape and passing through the first conductive plate and the second conductive plate in a thickness direction, and
the output part includes a plurality of second passing holes provided to an end part of a part corresponding to a leg part of a T-like shape and passing through the first conductive plate and the second conductive plate in a thickness direction.

### Appendix 5

The power conversion apparatus according to Appendix 4, wherein
the insulating layer is an insulating object inserted between the first conductive plate and the second conductive plate, and
the insulating object has a T-like shape in a plan view, and has a size and a shape so as not to cover an arrangement of the plurality of first passing holes and an arrangement of the plurality of second passing holes.

### Appendix 6

The power conversion apparatus according to Appendix 5, further comprising
a first spacer and a second spacer as conductors inserted into regions in which an arrangement of the plurality of first passing holes and an arrangement of the plurality of second passing holes are provided in the first conductive plate and the second conductive plate, respectively, wherein
the first spacer and the second spacer include a plurality of third passing holes and a plurality of fourth passing holes corresponding to the plurality of first passing holes and the plurality of second passing holes, respectively.

### Appendix 7

The power conversion apparatus according to Appendix 4, comprising
a first spacer and a second spacer as conductors inserted into regions in which an arrangement of the plurality of first passing holes and an arrangement of the plurality of second passing holes are provided in the first conductive plate and the second conductive plate, respectively, wherein
the first spacer and the second spacer include a plurality of third passing holes and a plurality of fourth passing holes corresponding to the plurality of first passing holes and the plurality of second passing holes, respectively, and
the insulating layer is made up of an air layer located in a gap formed in a region in which the first spacer and the second spacer are not provided.

### Appendix 8

The power conversion apparatus according to Appendix 4, wherein
at least one of the first conductive plate and the second conductive plate includes a concave part formed in a region in which the insulating layer is provided,
the concave part has a T-like shape in a plan view, and has a size and a shape so as not to reach an arrangement of the plurality of first passing holes and an arrangement of the plurality of second passing holes, and
the insulating layer is made up of an air layer located in a gap formed by the concave part between the first conductive plate and the second conductive plate.

### Appendix 9

The power conversion apparatus according to any one of Appendixes 4 to 8, wherein
each of the first conductive plate and the second conductive plate includes a notch part having an elongated shape in a plan view provided to pass through a center part of a part corresponding to a head part of a T-like shape in parallel to an arrangement of the plurality of first passing holes.

### Appendix 10

The power conversion apparatus according to any one of Appendixes 4 to 8, wherein
each of the first conductive plate and the second conductive plate includes a notch part having an elongated shape in a plan view provided to pass through a part closer to the plurality of first passing holes in relation to a center part of a part corresponding to a head part of a T-like shape in parallel to an arrangement of the plurality of first passing holes.

### Appendix 11

The power conversion apparatus according to Appendix 4, wherein
the plurality of second passing holes are provided in a row at an oblique angle with respect to a short side of the leg part.

### Appendix 12

The power conversion apparatus according to Appendix 4, wherein
the first conductive plate and the second conductive plate have a same shape.

### Appendix 13

The power conversion apparatus according to any one of Appendixes 1 to 12, wherein
a direction of current flowing in the upper plate is a same as a direction of current flowing in the lower plate in a part in which the insulating layer is provided between the upper plate and the lower plate.

While the disclosure has been shown and described in detail, the foregoing description is in all aspects illustrative and not restrictive. It is therefore understood that numerous modifications and variations can be devised.

What is claimed is:

1. A power conversion apparatus converting direct electrical power to alternating electrical power, comprising:
a plurality of semiconductor modules; and
an alternating current busbar connected in common to output terminals of the plurality of semiconductor modules, wherein
the alternating current busbar
has a multilayer structure divided into a plurality of pieces in a thickness direction, and
includes an insulating layer partially provided between an upper plate on an upper side and a lower plate on a lower side.

2. The power conversion apparatus according to claim 1, wherein
each of the upper plate and the lower plate includes an input part connected to the plurality of semiconductor modules and an output part connected to an outer part, and
the upper plate and the lower plate are electrically connected in the input part and the output part.

3. The power conversion apparatus according to claim 1, wherein
each of the upper plate and the lower plate includes an input part connected to the plurality of semiconductor modules and an output part connected to an outer part, and
the input part and the output part are provided on sides opposite to each other in a plan view.

4. The power conversion apparatus according to claim 2, wherein
the upper plate is a first conductive plate having a T-like shape in a plan view,
the lower plate is a second conductive plate having a T-like shape in a plan view,
the input part includes a plurality of first passing holes provided to one long side of a part corresponding to a head part of a T-like shape and passing through the first conductive plate and the second conductive plate in a thickness direction, and
the output part includes a plurality of second passing holes provided to an end part of a part corresponding to a leg part of a T-like shape and passing through the first conductive plate and the second conductive plate in a thickness direction.

5. The power conversion apparatus according to claim 4, wherein
the insulating layer is an insulating object inserted between the first conductive plate and the second conductive plate, and
the insulating object has a T-like shape in a plan view, and has a size and a shape so as not to cover an arrangement of the plurality of first passing holes and an arrangement of the plurality of second passing holes.

6. The power conversion apparatus according to claim 5, further comprising
a first spacer and a second spacer as conductors inserted into regions in which an arrangement of the plurality of first passing holes and an arrangement of the plurality of second passing holes are provided in the first conductive plate and the second conductive plate, respectively, wherein
the first spacer and the second spacer include a plurality of third passing holes and a plurality of fourth passing holes corresponding to the plurality of first passing holes and the plurality of second passing holes, respectively.

7. The power conversion apparatus according to claim 4, comprising
a first spacer and a second spacer as conductors inserted into regions in which an arrangement of the plurality of first passing holes and an arrangement of the plurality of second passing holes are provided in the first conductive plate and the second conductive plate, respectively, wherein
the first spacer and the second spacer include a plurality of third passing holes and a plurality of fourth passing holes corresponding to the plurality of first passing holes and the plurality of second passing holes, respectively, and
the insulating layer is made up of an air layer located in a gap formed in a region in which the first spacer and the second spacer are not provided.

8. The power conversion apparatus according to claim 4, wherein
at least one of the first conductive plate and the second conductive plate includes a concave part formed in a region in which the insulating layer is provided,
the concave part has a T-like shape in a plan view, and has a size and a shape so as not to reach an arrangement of the plurality of first passing holes and an arrangement of the plurality of second passing holes, and
the insulating layer is made up of an air layer located in a gap formed by the concave part between the first conductive plate and the second conductive plate.

9. The power conversion apparatus according to claim 4, wherein
each of the first conductive plate and the second conductive plate includes a notch part having an elongated shape in a plan view provided to pass through a center part of a part corresponding to a head part of a T-like shape in parallel to an arrangement of the plurality of first passing holes.

10. The power conversion apparatus according to claim 4, wherein
each of the first conductive plate and the second conductive plate includes a notch part having an elongated shape in a plan view provided to pass through a part closer to the plurality of first passing holes in relation to a center part of a part corresponding to a head part of a T-like shape in parallel to an arrangement of the plurality of first passing holes.

11. The power conversion apparatus according to claim 4, wherein
the plurality of second passing holes are provided in a row at an oblique angle with respect to a short side of the leg part.

12. The power conversion apparatus according to claim 4, wherein
the first conductive plate and the second conductive plate have a same shape.

13. The power conversion apparatus according to claim 1, wherein
a direction of current flowing in the upper plate is a same as a direction of current flowing in the lower plate in a part in which the insulating layer is provided between the upper plate and the lower plate.

14. The power conversion apparatus according to claim 3, wherein
the upper plate is a first conductive plate having a T-like shape in a plan view,
the lower plate is a second conductive plate having a T-like shape in a plan view,
the input part includes a plurality of first passing holes provided to one long side of a part corresponding to a head part of a T-like shape and passing through the first conductive plate and the second conductive plate in a thickness direction, and
the output part includes a plurality of second passing holes provided to an end part of a part corresponding to a leg part of a T-like shape and passing through the first conductive plate and the second conductive plate in a thickness direction.

15. The power conversion apparatus according to claim 14, wherein
the insulating layer is an insulating object inserted between the first conductive plate and the second conductive plate, and
the insulating object has a T-like shape in a plan view, and has a size and a shape so as not to cover an arrangement of the plurality of first passing holes and an arrangement of the plurality of second passing holes.

16. The power conversion apparatus according to claim 15, further comprising
a first spacer and a second spacer as conductors inserted into regions in which an arrangement of the plurality of first passing holes and an arrangement of the plurality of second passing holes are provided in the first conductive plate and the second conductive plate, respectively, wherein
the first spacer and the second spacer include a plurality of third passing holes and a plurality of fourth passing holes corresponding to the plurality of first passing holes and the plurality of second passing holes, respectively.

17. The power conversion apparatus according to claim 14, comprising
a first spacer and a second spacer as conductors inserted into regions in which an arrangement of the plurality of first passing holes and an arrangement of the plurality of second passing holes are provided in the first conductive plate and the second conductive plate, respectively, wherein
the first spacer and the second spacer include a plurality of third passing holes and a plurality of fourth passing holes corresponding to the plurality of first passing holes and the plurality of second passing holes, respectively, and
the insulating layer is made up of an air layer located in a gap formed in a region in which the first spacer and the second spacer are not provided.

18. The power conversion apparatus according to claim 14, wherein
at least one of the first conductive plate and the second conductive plate includes a concave part formed in a region in which the insulating layer is provided,
the concave part has a T-like shape in a plan view, and has a size and a shape so as not to reach an arrangement of the plurality of first passing holes and an arrangement of the plurality of second passing holes, and
the insulating layer is made up of an air layer located in a gap formed by the concave part between the first conductive plate and the second conductive plate.

19. The power conversion apparatus according to claim 14, wherein
each of the first conductive plate and the second conductive plate includes a notch part having an elongated shape in a plan view provided to pass through a center part of a part corresponding to a head part of a T-like shape in parallel to an arrangement of the plurality of first passing holes.

20. The power conversion apparatus according to claim 14, wherein
each of the first conductive plate and the second conductive plate includes a notch part having an elongated shape in a plan view provided to pass through a part closer to the plurality of first passing holes in relation to a center part of a part corresponding to a head part of a T-like shape in parallel to an arrangement of the plurality of first passing holes.

21. The power conversion apparatus according to claim 14, wherein
the plurality of second passing holes are provided in a row at an oblique angle with respect to a short side of the leg part.

22. The power conversion apparatus according to claim 14, wherein
the first conductive plate and the second conductive plate have a same shape.
